(19) United States
(12) Patent Application Publication
(10) Pub. No.: US 2013/0161469 A1
(43) Pub. Date: Jun. 27, 2013

(54) MOUNTING APPARATUS FOR EXPANSION CARD

(71) Applicants: YUN-LUNG CHEN, Tu-Cheng (TW); LIANG-CHIN WANG, Tu-Cheng (TW); YU-MING XIAO, Wuhan City (CN); LIN DING, Wuhan City (CN); ZAN LI, Wuhan City (CN); JUN WANG, Wuhan City (CN)

(72) Inventors: YUN-LUNG CHEN, Tu-Cheng (TW); LIANG-CHIN WANG, Tu-Cheng (TW); YU-MING XIAO, Wuhan City (CN); LIN DING, Wuhan City (CN); ZAN LI, Wuhan City (CN); JUN WANG, Wuhan City (CN)

(73) Assignees: HON HAI PRECISION INDUSTRY CO., LTD., Tu-Cheng (TW); HONG FU JIN PRECISION INDUSTRY (WuHan) CO., LTD., Wuhan City (CN)

(21) Appl. No.: 13/482,470

(22) Filed: May 29, 2012

(30) Foreign Application Priority Data
Dec. 23, 2011 (CN) 201110437312.5

(51) Int. Cl. H05K 7/00

(52) U.S. Cl. 248/316.7; 248/309.1

(57) ABSTRACT

A mounting apparatus includes a chassis, a mounting piece and a securing member. The chassis includes a rear plate and a side plate. The rear plate includes a supporting panel, and a positioning slot is defined in the rear plate. The side plate includes a flange. The mounting piece includes an engaging portion. The securing member includes a first securing panel rotatably attached to the supporting panel and a second securing panel. A retaining piece extends from the second securing panel in a first direction, and a positioning piece extends from the second securing panel in a second direction substantially perpendicular to the first direction. The retaining piece is engaged in the positioning slot, the positioning piece is located between the flange and the rear plate, and the flange is secured to the rear plate.

### BACKGROUND

1. Technical Field

The present disclosure relates to mounting apparatuses, more particularly to a mounting apparatus for an expansion card.

2. Description of Related Art

A computer system usually includes expansion cards, such as sound cards, video cards, graphics cards, for enhancing capacities of the computer system. The expansion cards are often mounted to a computer casing of the computer system with screws. However, using screws to attach the expansion cards is laborious and time consuming. Therefore, an improved mounting apparatus may be needed within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus for an expansion card in accordance with an embodiment.

FIG. 2 is an isometric view of a securing member of the mounting apparatus of FIG. 1.

FIG. 3 is similar to FIG. 1, but viewed in a different aspect.

FIG. 4 is an assembled view of FIG. 1.

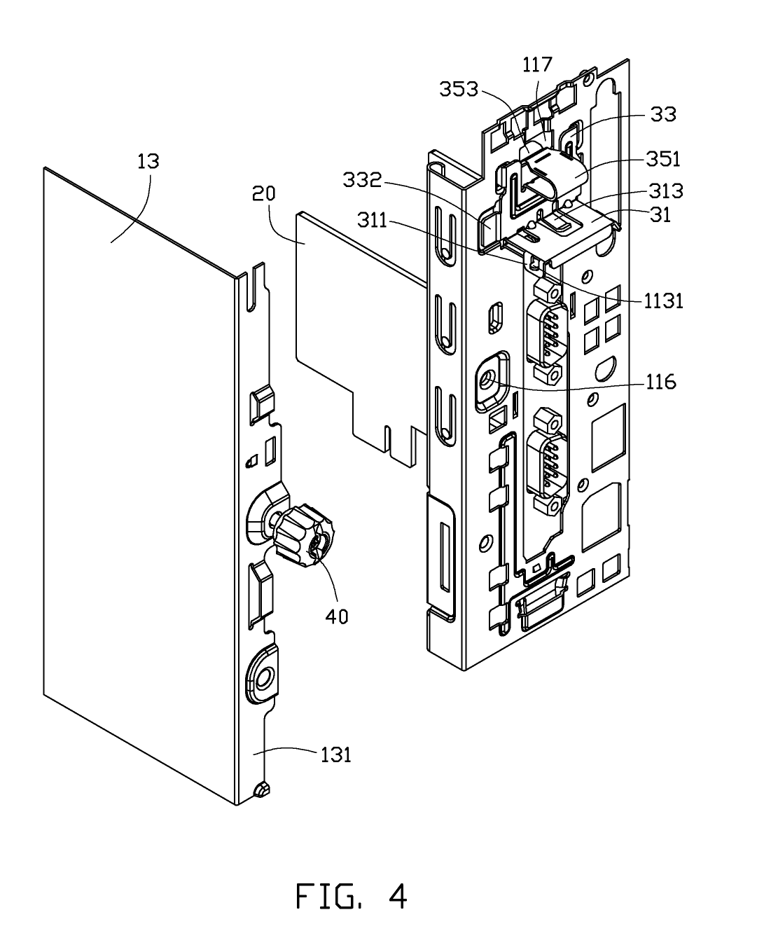

FIG. 5 is similar to FIG. 4, but viewed in a different aspect.

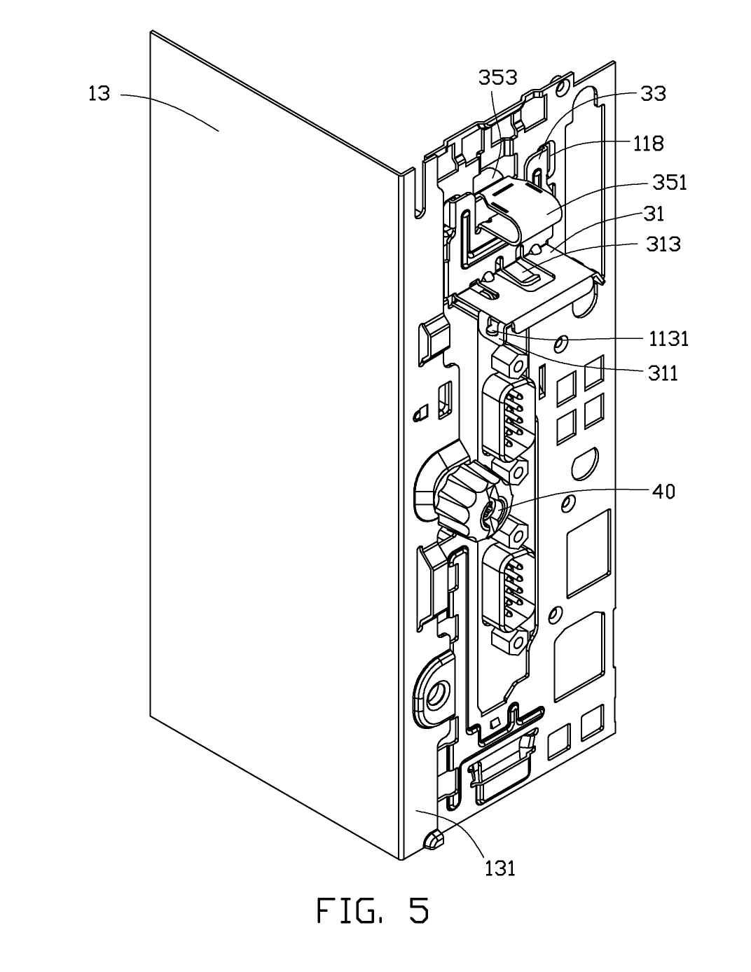

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

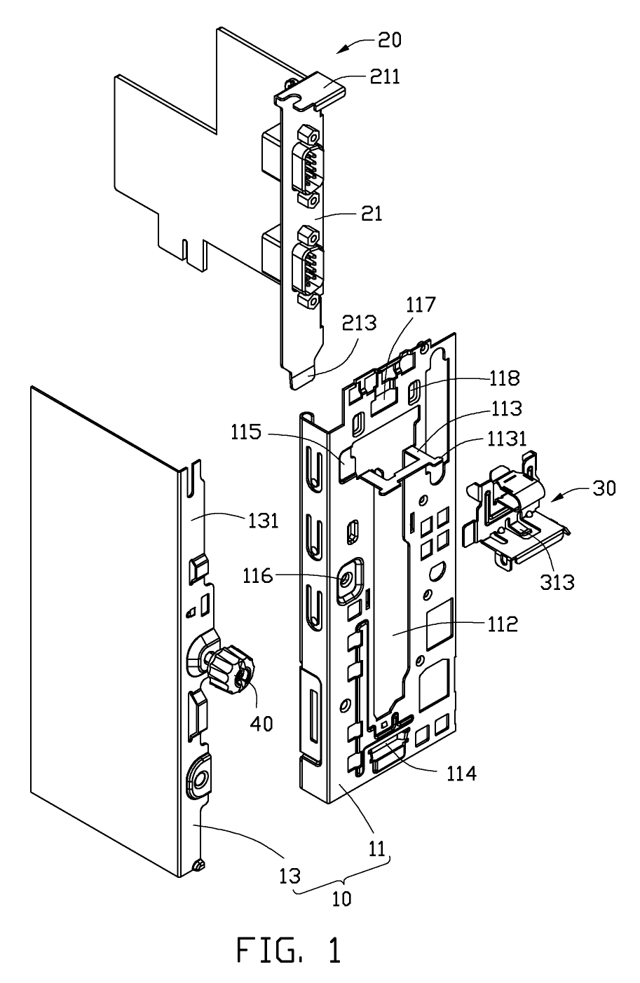

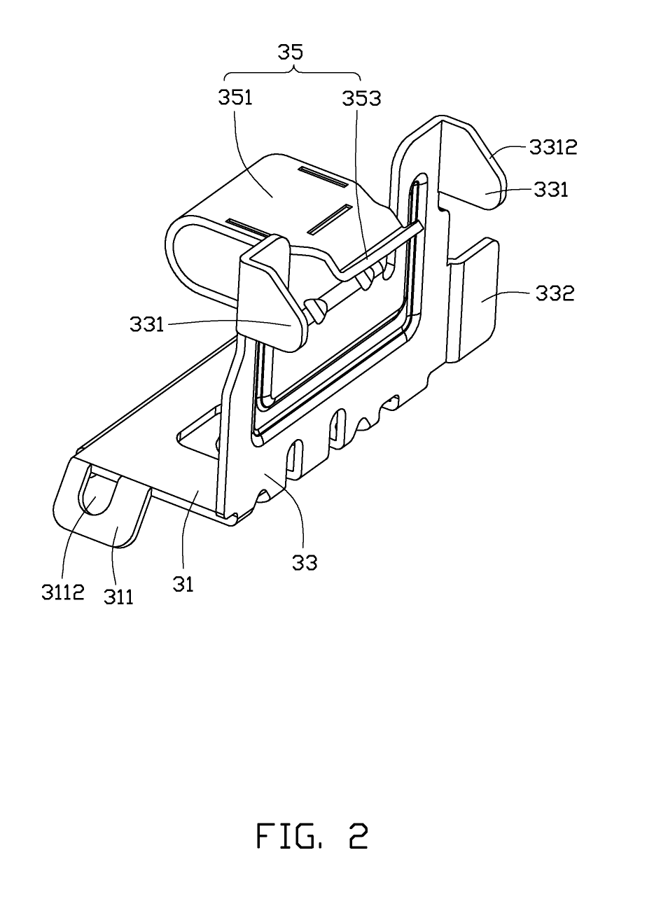

FIGS. 1 and 2, illustrate a mounting apparatus in accordance with an embodiment including a chassis 10 and a securing member 30 for securing an expansion card 20 to the chassis 10. In one embodiment, the expansion card 20 may be, for example, one or more sound cards, video cards, or graphics cards, or other peripheral component interconnection (PCI) cards.

The chassis 10 includes a rear plate 11 and a side plate 13 attached to the rear plate 11. The rear plate 11 defines an expansion slot 112 and an inserting slot 114 under the expansion slot 112. A supporting panel 113 is located on the rear plate 11, and two pivoting portions 1131 extend from opposite ends of the supporting panel 113. A receiving portion 115 is located on the rear plate 11 and adjacent to the expansion slot 112. A securing hole 116, a clipping hole 117 and two positioning slots 118 are defined in the rear plate 11. The securing hole 116 is under the receiving portion 115. The clipping hole 117 is above the expansion slot 112, and the two positioning slots 118 are distributed on opposite sides of the clipping hole 117. In one embodiment, each of the two positioning slots 18 is a rectangle.

The side plate 13 includes a flange 131. A mounting member 40, such as a screw, is moveably attached to the side plate 13. In one embodiment, the flange 131 is substantially perpendicular to the side plate 13.

A mounting piece 21 is attached to the expansion card 20. An engaging portion 211 extends from a first end of the mounting piece 21, and an inserting portion 213 extends from a second end of the mounting piece 21.

The securing member 30 includes a first securing panel 31, a second securing panel 33 connected to the first securing panel 31, and a clipping panel 35 located on the second securing panel 33. In one embodiment, the second securing panel 33 is substantially perpendicular to the first securing panel 31. Two pivoting pieces 311 extend from opposite edges of the first securing panel 31. A pivoting hole 3112 is defined in each of the two pivoting pieces 311. An elastic piece 313 is located on the first securing panel 31 and connected to the second securing panel 33. In one embodiment, each of the two pivoting pieces 311 is deformable between a first position and a second position, in the first position, each of the two pivoting pieces 311 is substantially perpendicular to the first securing panel 31; in the second position, an obtuse angle is defined between the first securing panel 31 and each of the two pivoting pieces 311.

Two retaining pieces 331 extend from opposite edges of the second securing panel 33. Each of the two retaining pieces 331 includes a slanted edge 3312. A positioning piece 332 extends from an edge of the second securing panel 33. In one embodiment, an extending direction of the positioning piece 332 is substantially perpendicular to that of each of the two retaining pieces 331.

The clipping panel 35 includes a resilient arm 351 connected to the second securing panel 33, and a clipping portion 353 is located on the free end of the resilient arm 351. In one embodiment, the resilient arm 351 is U-shaped, and the clipping portion 353 is V-shaped.

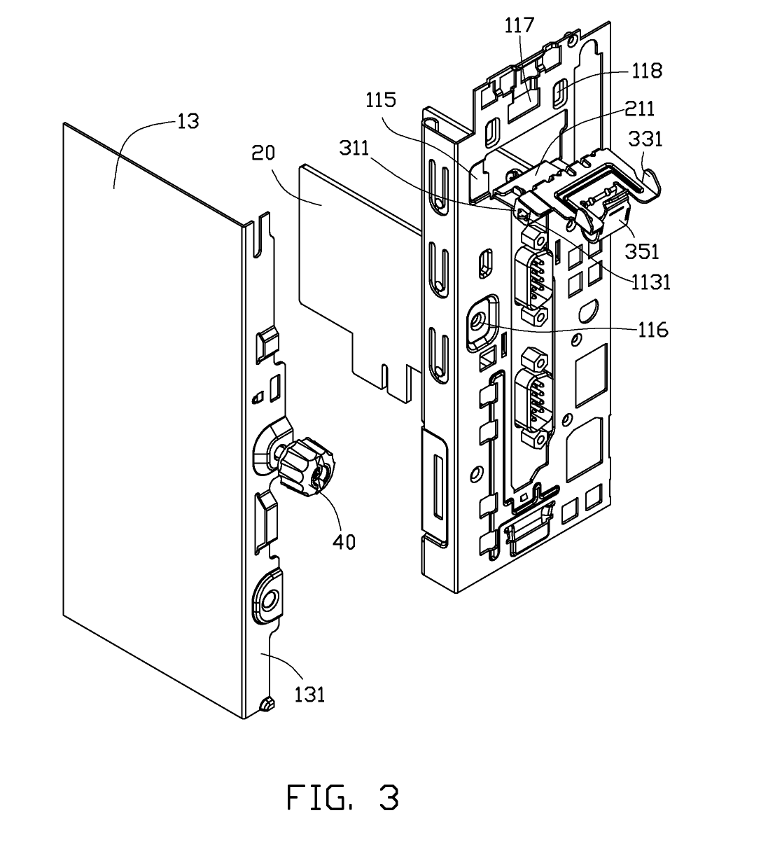

FIG. 3, shows in assembly, the inserting portion 213 is engaged in the inserting slot 114, and the engaging portion 211 abuts the supporting panel 113. The two pivoting pieces 311 deform to be located in the second position. The first securing panel 31 is placed on the supporting panel 113, and the two pivoting portions 1131 are engaged in the two pivoting holes 3112, to rotatably secure the securing member 30 to the supporting panel 113. The securing member 30 is rotated towards the rear plate 11, until the two retaining pieces 331 are inserted into the two positioning slots 118, and the clipping portion 353 is clipped into the clipping hole 117. At this point, the positioning piece 332 is received in the receiving portion 115, and the resilient arm 351 abuts the engaging portion 211. The two pivoting pieces 311 are released to be located in the first position, and the securing member 30 is secured to the rear plate 11.

The side plate 13 covers the rear plate 11, and the flange 131 abuts the rear plate 11. Thus, the flange 131 abuts the positioning piece 332. The mounting member 40 is engaged in the securing hole 116, to secure the flange 131 to the rear plate 11. Therefore, the flange 131 can prevent the positioning piece 332 from being disengaged from the receiving portion 115.

In disassembly, the mounting member 40 is detached from the flange 131, to detach the flange 131 from the rear plate 11. The resilient arm 351 is deformed to disengage the clipping portion 353 from the clipping hole 117. The retaining pieces 331 are removed from the two positioning holes 118. The securing member 30 is rotated away from the rear plate 11, and the positioning piece 332 is disengaged from the receiving portion 115. The first securing panel 31 is disengaged from the engaging portion 211. The two pivoting pieces 311 deform to be located in the second position, removing the two pivoting pieces 311 from the two pivoting holes 3112. Thus, the securing member 30 can be detached from the supporting panel 113. The engaging portion 211 is disengaged from the supporting panel, and the inserting portion 213 is removed from the inserting slot 114. Therefore, the expansion card 20 is detached from the rear plate 11.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a chassis comprising a rear plate and a side plate; the rear plate comprising a supporting panel, and a positioning slot defined in the rear plate; the side plate comprising a flange;
a mounting piece adapted to be attached to an expansion card, comprising an engaging portion; and
a securing member comprising a first securing panel and a second securing panel connected to the first securing panel, the first securing panel being rotatably attached to the supporting panel so that the engaging portion is sandwiched between the supporting panel and the first securing panel; a retaining piece extending from the second securing panel in a first direction, and a positioning piece extending from the second securing panel in a second direction, the second direction being substantially perpendicular to the first direction;
wherein the retaining piece is engaged in the positioning slot, the positioning piece is located between the flange and the rear plate, and the flange is secured to the rear plate thereby preventing the positioning piece from disengaging from the rear plate.

2. The mounting apparatus of claim 1, wherein the rear plate comprises a receiving portion, and the positioning piece is engaged with the receiving portion.

3. The mounting apparatus of claim 1, wherein a pivoting portion extends from an end of the supporting panel, the first securing panel comprises a pivoting piece, and the pivoting piece is rotatably secured to the pivoting portion.

4. The mounting apparatus of claim 3, wherein the pivoting piece is deformable relative to the first securing panel between a first position and a second position; in the first position, the pivoting piece is substantially perpendicular to the first securing panel; and in the second position, an obtuse angle is defined between the pivoting piece and the first securing panel.

5. The mounting apparatus of claim 1, wherein the retaining piece comprises a slanted edge, and the retaining piece extends through the positioning slot along the slanted edge.

6. The mounting apparatus of claim 1, wherein the first securing panel comprises an elastic piece abutting the engaging portion, and the elastic piece is connected to the second securing panel.

7. The mounting apparatus of claim 1, wherein the securing member further comprises a clipping panel connected to the second securing panel, the clipping panel comprises a clipping portion, the rear plate defines a clipping hole, the clipping portion is received in the clipping hole.

8. The mounting apparatus of claim 7, wherein the clipping portion is V-shaped.

9. The mounting apparatus of claim 7, wherein the clipping panel further comprises a resilient arm, the clipping portion is connected to a free end of the resilient arm, and the resilient arm is deformable to disengage the clipping portion from the clipping hole.

10. The mounting apparatus of claim 8, wherein the resilient arm is U-shaped.

11. A mounting apparatus comprising:
a chassis comprising a rear plate and a side plate substantially perpendicular to the rear plate; the rear plate comprising a supporting panel and a positioning slot; a pivoting portion extending from an end of the supporting panel;
a mounting piece adapted to be attached to an expansion card, comprising an engaging portion; and
a securing member comprising a first securing panel and a second securing panel connected to the first securing panel, the first securing panel being rotatably attached to the supporting panel so that the engaging portion is sandwiched between the supporting panel and the first securing panel; a pivoting piece extending from the first securing panel; and a retaining piece extending from the second securing panel in a first direction;
wherein the retaining piece is engaged in the positioning slot, the pivoting piece is deformable relative to the first securing panel between a first position and a second position; in the first position, the pivoting piece is substantially perpendicular to the first securing panel to rotatably engage with the pivoting portion; and in the second position, an obtuse angle is defined between the pivoting piece and the first securing panel thereby disengaging pivoting piece from the pivoting portion.

12. The mounting apparatus of claim 11, wherein the side plate comprises a flange, the second securing panel comprises a positioning piece located between the flange and the rear plate, the positioning piece extending from the second securing panel in a second direction substantially perpendicular to the first direction, and the flange is secured to the rear plate thereby preventing the positioning piece from disengaging from the rear plate.

13. The mounting apparatus of claim 12, wherein the rear plate comprises a receiving portion, and the positioning piece is engaged with the receiving portion.

14. The mounting apparatus of claim 11, wherein the retaining piece comprises a slanted edge, and the retaining piece extends through the positioning slot along the slanted edge.

15. The mounting apparatus of claim 11, wherein the first securing panel comprises an elastic piece abutting the engaging portion, and the elastic piece is connected to the second securing panel.

16. The mounting apparatus of claim 11, wherein the securing member further comprises a clipping panel connected to the second securing panel, the clipping panel comprises a clipping portion, the rear plate defines a clipping hole, the clipping portion is received in the clipping hole.

17. The mounting apparatus of claim 16, wherein the clipping portion is V-shaped.

18. The mounting apparatus of claim 11, wherein the clipping panel further comprises a resilient arm, the clipping portion is connected to a free end of the resilient arm, and the resilient arm is deformable to disengage the clipping portion from the clipping hole.

19. The mounting apparatus of claim 18, wherein the resilient arm is U-shaped.
